(19) United States
(12) Patent Application Publication
(10) Pub. No.: US 2026/0136490 A1
(43) Pub. Date: May 14, 2026

(54) INNER TANK ASSEMBLY AND IMMERSION COOLING TANK

(71) Applicant: Wiwynn Corporation, New Taipei City (TW)

(72) Inventors: HSIEN-CHIEH HSIEH, New Taipei City (TW); Fu Sheng Cheng, New Taipei City (TW); Jing-Suei Gao, New Taipei City (TW)

(21) Appl. No.: 19/363,768

(22) Filed: Oct. 21, 2025

Related U.S. Application Data
(60) Provisional application No. 63/717,960, filed on Nov. 8, 2024.

(30) Foreign Application Priority Data
Jun. 9, 2025 (TW) 114205883

(51) Int. Cl. H05K 7/20; H05K 7/14

(52) U.S. Cl. CPC H05K 7/20236; H05K 7/1418

(57) ABSTRACT

An inner tank assembly is configured to accommodate a plurality of electronic devices. The inner tank assembly includes a bottom plate, four sidewalls, a bracket, and a busbar. The four sidewalls are connected to the bottom plate, and one of the four sidewalls is provided with an opening. The bracket is disposed on the bottom plate. The busbar is slidably mounted on the bracket through the opening and configured to provide electricity to the electronic devices.

### CROSS-REFERENCE TO RELATED APPLICATIONS

This non-provisional application claims priority under 35 U.S.C. § 119(a) on Provisional Application No(s). 63/717,960 filed in U.S.A on November 8th, 2024, and Patent Application No(s). 114205883 filed in Taiwan, R.O.C. on June 9th, 2025, the entire contents of which are hereby incorporated by reference.

### TECHNICAL FIELD

The disclosure relates to an inner tank assembly and an immersion cooling tank.

### BACKGROUND

With the advancement and development of technology, servers are currently cooled by being immersed in coolant within a tank. Conventionally, an inner tank is welded in an outer tank, and when the inner tank needs to be replaced, it cannot be separated from the outer tank, resulting in the need to replace the entire tank assembly. Additionally, the busbar for supplying power to the servers is installed at the bottom of the inner tank, making the installation and removal of the busbar difficult and inconvenient. Therefore, how to address the aforementioned issues is one of the topics in this field.

### SUMMARY

Accordingly, the disclosure is to provide an inner tank assembly and an immersion cooling tank enable the inner tank assembly to be separated from the outer tank when replacement is needed, and enable the busbar to be assembled and disassembled easily.

One embodiment of the disclosure provides an inner tank assembly. The inner tank assembly is configured to accommodate a plurality of electronic devices. The inner tank assembly includes a bottom plate, four sidewalls, a bracket and a busbar. The four sidewalls are connected to the bottom plate, and one of the four sidewalls is provided with an opening. The bracket is disposed on the bottom plate. The busbar is slidably mounted on the bracket through the opening and configured to provide electricity to the electronic devices.

Another embodiment of the disclosure provides an immersion cooling tank. The immersion cooling tank includes an outer tank and the aforementioned inner tank assembly. The inner tank assembly is configured to accommodate the electronic devices and disposed in the outer tank.

The inner tank assembly and the immersion cooling tank of the disclosure have the following advantages: (1) The inner tank assembly and the multiple electronic devices accommodated therein can be moved into or out of the outer tank together, thereby enhancing assembly convenience. (2) The modular inner tank assembly increases versatility and design efficiency, making it suitable for immersion cooling tanks of any size as well as single-phase or two-phase liquid cooling systems. (3) By forming an opening on the sidewall of the inner tank assembly and arranging the busbar to be slidably assembled to the bracket on the bottom plate of the inner tank assembly through the opening, users can easily assemble or disassemble the busbar through the opening. (4) The inner tank assembly provides upper, middle, and bottom guidance to improve the installation accuracy of the electronic devices and prevent damage due to collision. (5) The inner tank assembly offers slot installation detection to detect whether each slot is equipped with an electronic device.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an immersion cooling tank and an electronic device according to one embodiment of the disclosure;

FIG. 2 is an exploded view of an inner tank assembly according to one embodiment of the disclosure;

FIG. 3 is an exploded view of an inner tank assembly according to one embodiment of the disclosure;

FIG. 4 is a partial perspective view of an inner tank assembly according to one embodiment of the disclosure; and

FIGS. 5 to 7 show an installation process of an electronic device into an inner tank assembly according to one embodiment of the disclosure.

### DETAILED DESCRIPTION

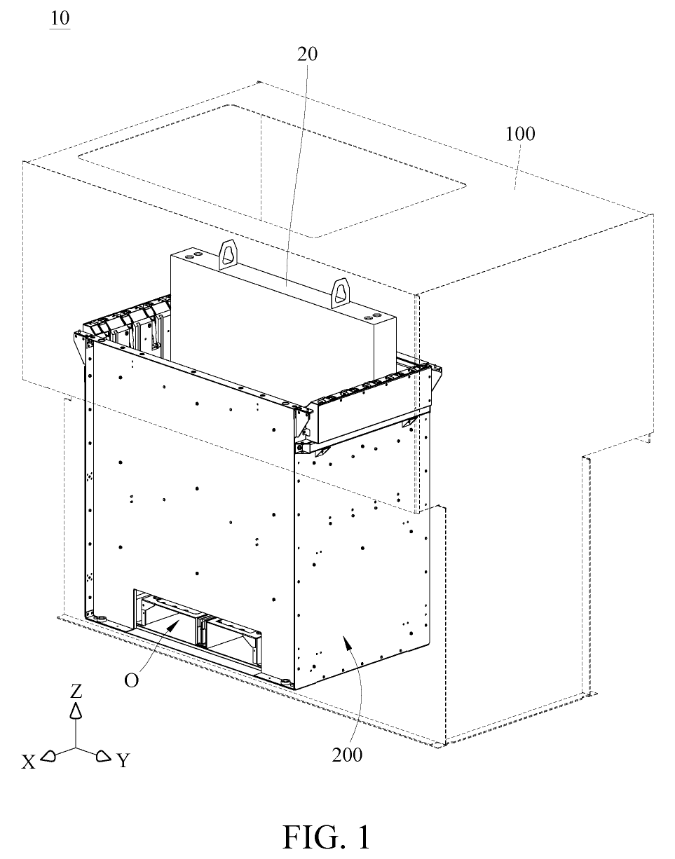

Referring to FIG. 1, FIG. 1 is a perspective view of an immersion cooling tank 10 and an electronic device 20 according to one embodiment of the disclosure. The immersion cooling tank 10 includes an outer tank 100 and an inner tank assembly 200. The inner tank assembly 200 is configured to accommodate a plurality of electronic devices 20 and a coolant (not shown), and the inner tank assembly 200 is disposed in the outer tank 100. In some embodiments, the electronic devices 20 are, for example, servers, and the coolant is, for example, a single-phase or two-phase coolant.

One installation method involves first placing the inner tank assembly 200 into the outer tank 100, and then installing the electronic devices 20 into the inner tank assembly 200. Another installation method involves first installing the electronic devices 20 into the inner tank assembly 200, and then installing the electronic devices 20 and the inner tank assembly 200 together into the outer tank 100. These two installation methods correspond to two disassembly methods. Accordingly, the disclosure provides multiple installation and disassembly methods to accommodate various operational requirements, such as single or batch installation and removal operations. Since the inner tank assembly 200 is provided with an opening O, regardless of whether the coolant is filled into the inner tank assembly 200 or the outer tank 100, the coolant can flow between the inner tank assembly 200 and the outer tank 100 through the opening O. During batch disassembly operations, that is, when the electronic devices 20 and the inner tank assembly 200 are removed from the outer tank 100 together, the coolant in the inner tank assembly 200 flows downward under gravity and flows through the opening O into the outer tank 100, thus no additional device is required to retrieve the coolant.

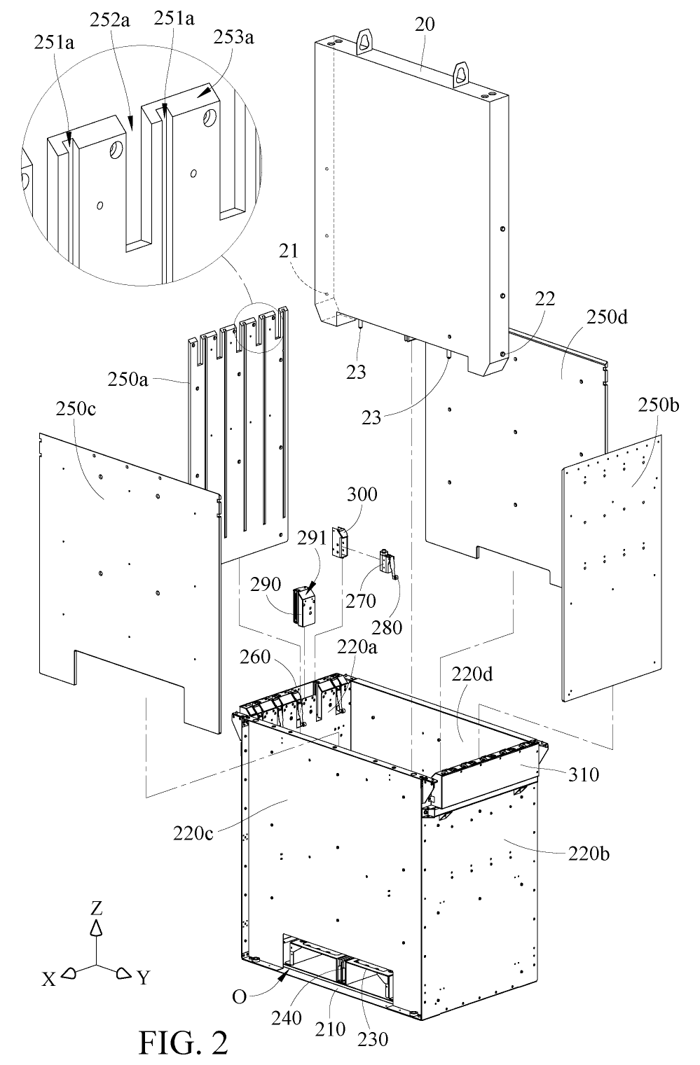

Referring to FIG. 2, FIG. 2 is an exploded view of the inner tank assembly 200 according to one embodiment of the disclosure. The inner tank assembly 200 includes a bottom plate 210, four sidewalls 220a, 220b, 220c and 220d, a bracket 230, and a busbar 240. The four sidewalls 220a-220d are connected to the bottom plate 210, and one of the sidewalls 220a-220d is provided with the opening O. The bracket 230 is disposed on the bottom plate 210. The busbar 240 is slidably mounted on the bracket 230 through the opening O along a X-direction and is configured to supply electricity to the electronic devices 20. When only the busbar 240 needs to be maintained or replaced, the electronic devices 20 and the inner tank assembly 200 can be removed from the outer tank 100 together, and the busbar 240 can be replaced by another one through the opening O. This enhances operational convenience and reduces downtime.

In some embodiments, the inner tank assembly 200 may further include four inner pads 250a, 250b, 250c and 250d. The four inner pads 250a-250d are respectively disposed on inner sides of the four sidewalls 220a-220d. Rigidities of the inner pads 250a-250d are less than that of casings of the electronic devices 20. The inner pads 250a-250d are made of softer materials to prevent scratching the casings of the electronic devices 20. In addition, the inner pads 250a-250d are made of non-conductive materials (e.g., bakelite), which helps prevent short circuits caused by metal debris floating in the inner tank assembly 200.

In some embodiments, a first inner pad 250a of the four inner pads 250a-250d is provided with a plurality of first guide grooves 251a. The first guide grooves 251a extend along a Z-direction and are configured to guide the electronic devices 20 into the inner tank assembly 200. The casing of the electronic device 20 is provided with at least one first guide protrusion 21. In operation, when the first guide protrusion 21 enters one of the first guide grooves 251a, the electronic device 20 is limited to be merely movable along the Z-direction. This helps prevent the electronic device 20 from wobbling during the movement process.

In some embodiments, the inner tank assembly 200 may further include a first partition 260, a plurality of presence detection circuits 270, and a plurality of detection units 280. The first partition 260 is disposed on an outer side of a first sidewall 220a of the four sidewalls 220a-220d. The presence detection circuits 270 are disposed in the first partition 260. The detection units 280 are respectively connected to the presence detection circuits 270 and are configured to detect the presences of the electronic devices 20. The first inner pad 250a is provided with a plurality of accommodation slots 252a. Each of the accommodation slots 252a is located between two of the first guide grooves 251a, and the detection units 280 are respectively disposed in the accommodation slots 252a.

In one embodiment, the presence detection circuit 270 and the detection unit 280 may be integrated as a limit switch. When the electronic device 20 is not installed in the inner tank assembly 200, the detection unit 280 protrudes from the accommodation slot 252a, and the presence detection circuit 270 is not triggered. Conversely, when the electronic device 20 enters the inner tank assembly 200, it interferes with the detection unit 280, causing the detection unit 280 to retract into the accommodation slot 252a, thereby triggering the presence detection circuit 270. Therefore, when the presence detection circuit 270 is triggered, the presence of the electronic device 20 in the inner tank assembly 200 can be detected.

In some embodiments, the inner tank assembly 200 may further include a plurality of first wedges 290 and a plurality of first covers 300. The first wedges 290 are disposed in the first partition 260 and are configured to guide the electronic devices 20 into the inner tank assembly 200. Each of the first covers 300 is disposed between two of the first wedges 290, and the first covers 300 are respectively configured to cover the presence detection circuits 270.

In some embodiments, first inclined surfaces 291 of the first wedges 290 abut a top inclined surface 253a of the first inner pad 250a, and widths of the first wedges 290 in a Y-direction gradually increase from a top toward a bottom of the inner tank assembly 200. In other words, a projection of the inner tank assembly 200 on a YZ plane has a funnel shape, which can guide the electronic devices 20 toward the interior of the inner tank assembly 200 along the first inclined surfaces 291 of the first wedges 290 and the top inclined surface 253a of the first inner pad 250a as the electronic devices 20 approach the inner tank assembly 200.

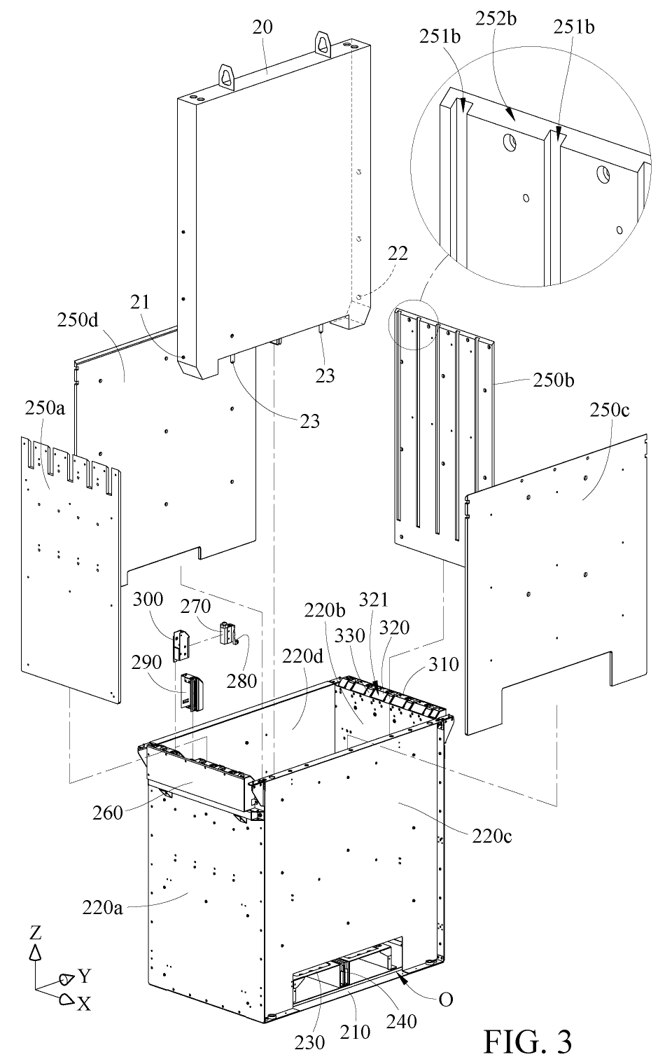

Referring to FIG. 3, FIG. 3 is an exploded view of the inner tank assembly 200 according to one embodiment of the disclosure. In some embodiments, a second inner pad 250b of the four inner pads 250a-250d is provided with a plurality of second guide grooves 251b. The second guide grooves 251b extend along the Z-direction and are configured to guide the electronic devices 20 into the inner tank assembly 200. The casing of the electronic device 20 is provided with at least one second guide protrusion 22. In operation, when the second guide protrusion 22 enters one of the second guide grooves 251b, the electronic device 20 is limited to be merely movable along the Z-direction. This helps prevent the electronic device 20 from wobbling during the movement process.

The first inner pad 250a and the second inner pad 250b are disposed opposite to each other, and widths of the first guide grooves 251a and widths of the second guide grooves 251b differ in the X-direction. Similarly, widths of the first guide protrusion 21 and widths of the second guide protrusion 22 on the casing of the electronic device 20 respectively correspond to the widths of the first guide grooves 251a and the widths of the second guide grooves 251b, and are therefore also different. Notably, the difference in widths between the first guide grooves 251a and the second guide grooves 251b helps prevent incorrect insertion of the electronic device 20 in the reverse orientation toward the busbar 240 at the bottom, thereby achieving a foolproof design.

In some embodiments, the inner tank assembly 200 may further include a second partition 310, a plurality of second wedges 320, and a plurality of second covers 330. The second partition 310 is disposed on an outer side of a second sidewall 220b of the four sidewalls 220a-220d. The second wedges 320 are disposed in the second partition 310 and are configured to guide the electronic devices 20 into the inner tank assembly 200. Each of the second covers 330 is disposed between two of the second wedges 320.

In some embodiments, second inclined surfaces 321 of the second wedges 320 abut a top inclined surface 252b of the second inner pad 250b, and widths of the second wedges 320 in the Y-direction gradually increase from the top toward the bottom of the inner tank assembly 200. In other words, the projection of the inner tank assembly 200 on the YZ plane have a funnel shape, which guides the electronic devices 20 toward the interior of the inner tank assembly 200 along the second inclined surfaces 321 of the second wedges 320 and the top inclined surface 252b of the second inner pad 250b as the electronic devices 20 approach the inner tank assembly 200.

In some embodiments, the opening O is formed on a third sidewall 220c of the four sidewalls 220a-220d and on a third inner pad 250c of the four inner pads 250a-250d, and the opening O is located at the bottom of the third sidewall 220c and the bottom of the third inner pad 250c.

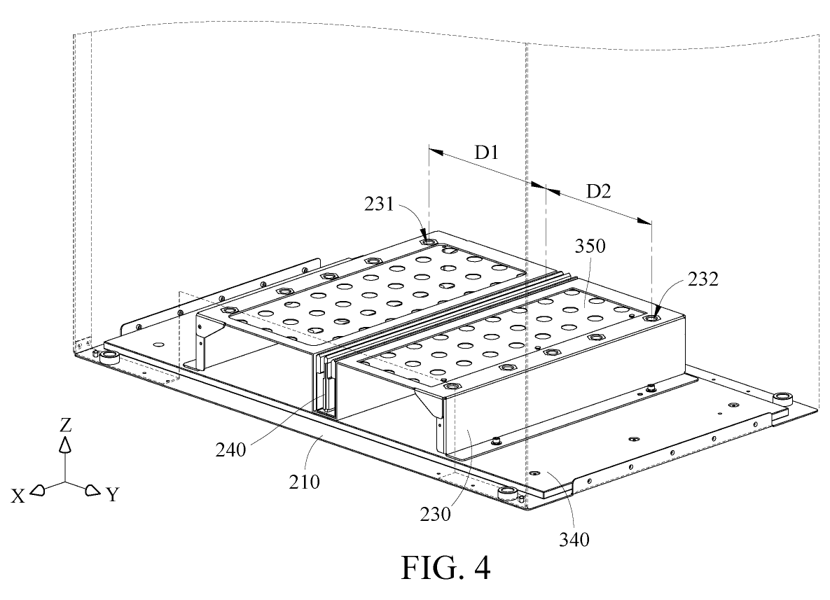

Referring to FIG. 4, FIG. 4 is a partial perspective view of the inner tank assembly 200 according to one embodiment of the disclosure. In some embodiments, the bracket 230 is provided with a plurality of guide holes 231, and the guide holes 231 are configured to receive guide pillars 23 of the electronic devices 20 (as shown in FIG. 2). Notably, before the electronic device 20 is inserted into the busbar 240, its guide pillars 23 are first inserted into the guide holes 231, thereby enabling preliminary alignment to improve the accuracy of inserting the electronic device 20 into the busbar 240.

In some embodiments, the bracket 230 is provided with a plurality of first guide holes 231 and a plurality of second guide holes 232. The busbar 240 is located between the first guide holes 231 and the second guide holes 232, and a first distance D1 between the first guide holes 231 and the busbar 240 is different from a second distance D2 between the second guide holes 232 and the busbar 240. This configuration prevents the electronic device 20 from being inserted into the busbar 240 in the reverse orientation, thereby achieving a foolproof design.

In some embodiments, the inner tank assembly 200 may further include a bottom pad 340 and a mesh plate 350. The bottom pad 340 is disposed on the bottom plate 210, and the bracket 230 is fixed to the bottom pad 340. The mesh plate 350 is connected to the bracket 230 and is disposed between the bottom pad 340 and the bracket 230 to regulate the flow field of the coolant. Notably, the coolant adopted in single-phase immersion cooling technology has relatively high viscosity, and the mesh plate 350 can adjust the flow field of the coolant accordingly.

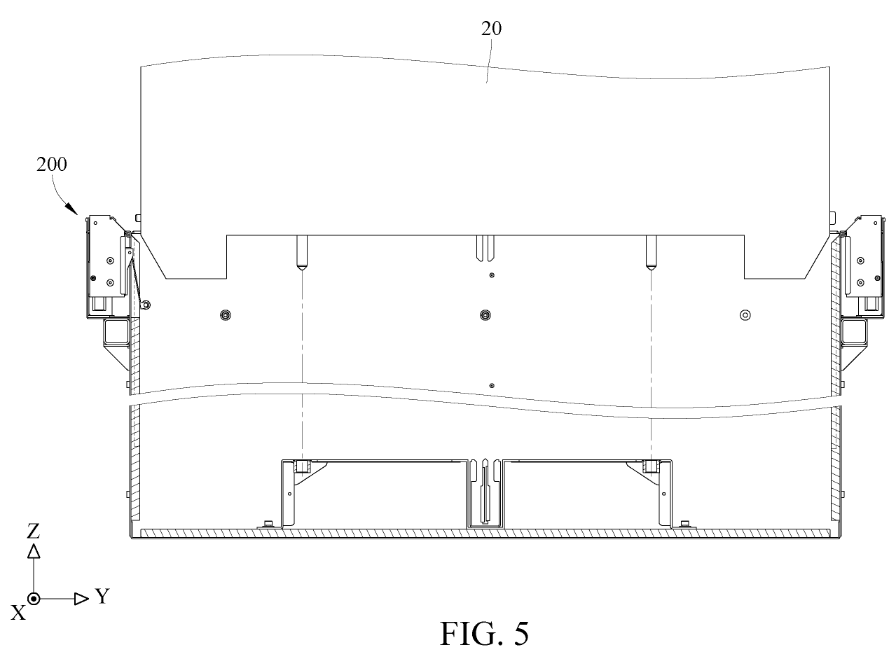

Referring to FIGS. 5 to 7, FIGS. 5 to 7 show an installation process of the electronic device 20 into the inner tank assembly 200 according to one embodiment of the disclosure. As shown in FIG. 5, the electronic device 20 may first be moved above the inner tank assembly 200 using a gantry crane. Then, the electronic device 20 is lowered along the Z-direction, allowing its bottom portion to be guided in the upper guidance provided by the first wedges 290 (as shown in FIG. 2) and the second wedges 320 (as shown in FIG. 3), thereby entering the inner tank assembly 200.

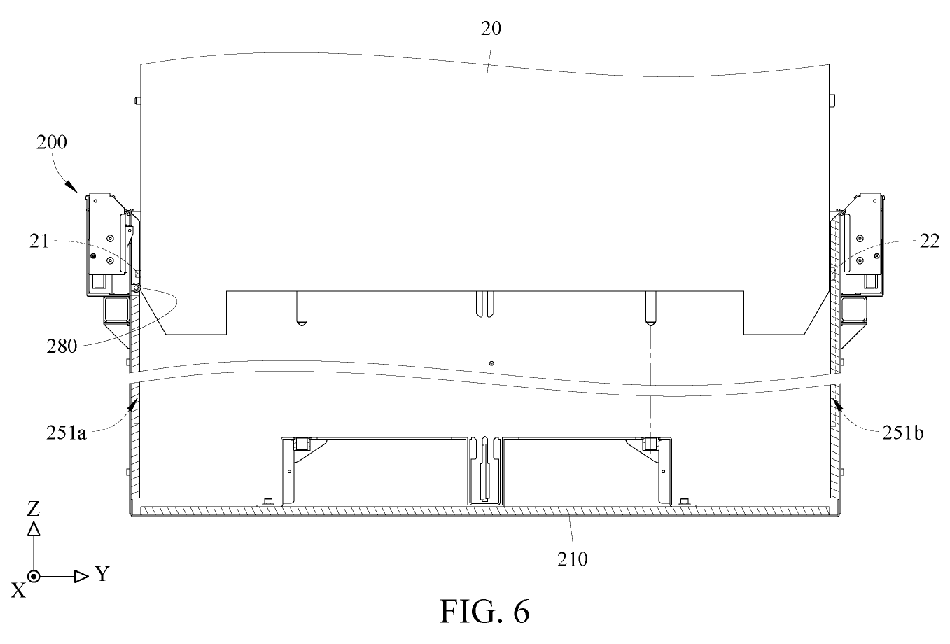

As shown in FIG. 6, during the process in which the electronic device 20 is moved toward the bottom plate 210 of the inner tank assembly 200, the first guide protrusion 21 and the second guide protrusion 22 of the electronic device 20 respectively enter the first guide groove 251a and the second guide groove 251b, thereby enabling the electronic device 20 to be guided in the middle guidance provided by the inner tank assembly 200. By designing the first guide groove 251a and the second guide groove 251b to have different widths, in combination with the different widths of the first guide protrusion 21 and the second guide protrusion 22, a foolproof mechanism can be achieved to prevent incorrect installation of the electronic device 20.

In addition, as shown in FIG. 6, during the movement of the electronic device 20 toward the bottom plate 210 of the inner tank assembly 200, the electronic device 20 contacts the detection unit 280, such that the corresponding presence detection circuit 270 (as shown in FIG. 2) transmits a signal to a monitoring system to indicate the presence of the electronic device 20.

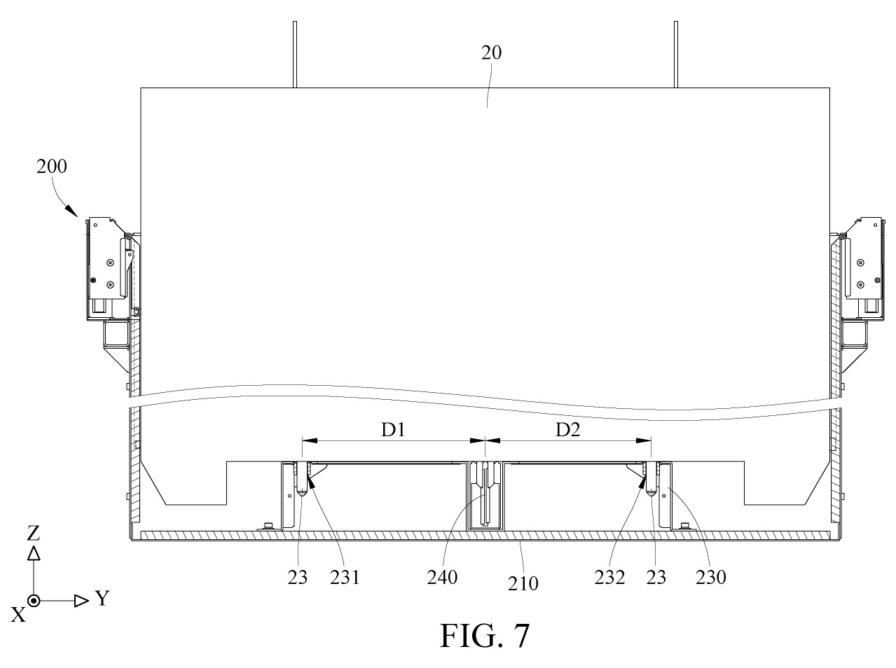

As shown in FIG. 7, when the electronic device 20 approaches the bottom plate 210 of the inner tank assembly 200, the guide pillars 23 of the electronic device 20 are inserted into the guide holes 231 and 232 of the bracket 230, thereby enabling the electronic device 20 to be guided in the bottom guidance provided by the inner tank assembly 200, achieving precise alignment between the electronic device 20 and the busbar 240. In this way, the electronic device 20 can be accurately connected to the busbar 240. Moreover, since the first distance D1 between the first guide hole 231 and the busbar 240 is different from the second distance D2 between the second guide hole 232 and the busbar 240, it prevents the electronic device 20 from being inserted into the bottom busbar 240 in the reverse orientation, thereby avoiding short circuit situations.

In summary, the inner tank assembly and the immersion cooling tank of the disclosure have the following advantages: (1) The inner tank assembly and the multiple electronic devices accommodated therein can be moved into or out of the outer tank together, thereby enhancing assembly convenience. (2) The modular inner tank assembly increases versatility and design efficiency, making it suitable for immersion cooling tanks of any size as well as single-phase or two-phase liquid cooling systems. (3) By forming an opening on the sidewall of the inner tank assembly and arranging the busbar to be slidably assembled to the bracket on the bottom plate of the inner tank assembly through the opening, users can easily assemble or disassemble the busbar through the opening. (4) The inner tank assembly provides upper, middle, and bottom guidance to improve the installation accuracy of the electronic devices and prevent damage due to collision. (5) The inner tank assembly offers slot installation detection to detect whether each slot is equipped with an electronic device.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. An inner tank assembly, configured to accommodate a plurality of electronic devices, comprising:
a bottom plate;
four sidewalls connected to the bottom plate, wherein one of the four sidewalls is provided with an opening;
a bracket disposed on the bottom plate; and
a busbar slidably mounted on the bracket through the opening and configured to provide electricity to the plurality of electronic devices.

2. The inner tank assembly according to claim 1, further comprising:
four inner pads respectively disposed on inner sides of the four sidewalls, wherein a first inner pad of the four inner pads is provided with a plurality of first guide grooves extending along a Z-direction and configured to guide the plurality of electronic devices into the inner tank assembly.

3. The inner tank assembly according to claim 2, wherein each of the plurality of electronic devices has a casing provided with at least one first guide protrusion; when the at least one first guide protrusion enters one of the plurality of first guide grooves, one of the plurality of electronic devices provided with the at least one first guide protrusion is limited to be merely movable along the Z-direction.

4. The inner tank assembly according to claim 2, further comprising:
a first partition disposed on an outer side a first sidewall of the four sidewalls;
a plurality of presence detection circuits disposed in the first partition; and
a plurality of detection units connected to the plurality of presence detection circuits and configured to detect presences of the plurality of electronic devices;
wherein the first inner pad is provided with a plurality of accommodation slots, each of the plurality of accommodation slots is located between two of the plurality of first guide grooves, and the plurality of detection units are respectively disposed in the plurality of accommodation slots.

5. The inner tank assembly according to claim 4, further comprising:
a plurality of first wedges disposed in the first partition and configured to guide the plurality of electronic devices into the inner tank assembly; and
a plurality of first covers, wherein each of the plurality of first covers is disposed between two of the plurality of first wedges, and the plurality of first covers are respectively configured to cover the plurality of presence detection circuits.

6. The inner tank assembly according to claim 5, wherein a plurality of first inclined surfaces of the plurality of first wedges abut a top inclined surface of the first inner pad, and widths of the plurality of first wedges in a Y-direction gradually increase from a top toward a bottom of the inner tank assembly.

7. The inner tank assembly according to claim 2, wherein:
a second inner pad of the four inner pads is provided with a plurality of second guide grooves extending along the Z-direction and configured to guide the plurality of electronic devices into the inner tank assembly; and
the first inner pad and the second inner pad are disposed opposite to each other, and widths of the plurality of first guide grooves and widths of the plurality of second guide grooves differ in a X-direction.

8. The inner tank assembly according to claim 7, wherein each of the plurality of electronic devices has a casing provided with at least one second guide protrusion; when the at least one second guide protrusion enters one of the plurality of second guide grooves, one of the plurality of electronic devices provided with the at least one second guide protrusion is limited to be merely movable along the Z-direction.

9. The inner tank assembly according to claim 7, further comprising:
a second partition disposed on an outer side of a second sidewall of the four sidewalls;
a plurality of second wedges disposed in the second partition and configured to guide the plurality of electronic devices into the inner tank assembly; and
a plurality of second covers, wherein each of the plurality of second covers are respectively disposed between two of the plurality of second wedges.

10. The inner tank assembly according to claim 9, wherein a plurality of second inclined surfaces of the plurality of second wedges abut a top inclined surface of the second inner pad, and widths of the plurality of second wedges in a Y-direction gradually increase from a top toward a bottom of the inner tank assembly.

11. The inner tank assembly according to claim 1, wherein the bracket is provided with a plurality of guide holes configured to receive guide pillars of the plurality of electronic devices.

12. The inner tank assembly according to claim 11, wherein the plurality of guide holes comprises a plurality of first guide holes and a plurality of second guide holes, the busbar is located between the plurality of first guide holes and the plurality of second guide holes, and a first distance between the plurality of first guide holes and the busbar is different from a second distance between the plurality of second guide holes and the busbar.

13. The inner tank assembly according to claim 2, wherein the opening is formed on a third sidewall of the four sidewalls and a third inner pad of the four inner pads, and the opening is located at a bottom of the third sidewall and a bottom of the third inner pad.

14. The inner tank assembly according to claim 2, wherein rigidities of the four inner pads are less than rigidities of casings of the plurality of electronic devices.

15. The inner tank assembly according to claim 1, further comprising:
a bottom pad disposed on the bottom plate, wherein the bracket is fixed to the bottom pad; and
a mesh plate connected to the bracket and disposed between the bottom pad and the bracket.

16. An immersion cooling tank, comprising:
an outer tank; and
the inner tank assembly according to claim 1 configured to accommodate the plurality of electronic devices and disposed in the outer tank.
